(19) United States
(12) Patent Application Publication
(10) Pub. No.: US 2011/0001219 A1
(43) Pub. Date: Jan. 6, 2011

(54) SILICON SINGLE CRYSTAL WAFER, METHOD FOR PRODUCING SILICON SINGLE CRYSTAL OR METHOD FOR PRODUCING SILICON SINGLE CRYSTAL WAFER, AND SEMICONDUCTOR DEVICE

(75) Inventors: Koji Ebara, Annaka (JP); Shizuo Igawa, Annaka (JP); Tetsuya Oka, Annaka (JP)

Correspondence Address: OLIFF & BERRIDGE, PLC, P.O. BOX 320850, ALEXANDRIA, VA, 22320-4850, US

(73) Assignee: Shin-Etsu Handotai Co., Ltd., Tokyo (JP)

(21) Appl. No.: 12/918,896

(22) PCT Filed: Feb. 19, 2009
(86) PCT No.: PCT/JP2009/000697

§ 371 Date: Aug. 23, 2010

(30) Foreign Application Priority Data
Apr. 2, 2008 (JP) 2008 096540

(51) Int. Cl. H01L 29/04; H01L 21/20; C30B 15/20

(52) U.S. Cl. 257/617; 438/9; 117/35; 257/E29.003; 257/E21.09

(57) ABSTRACT

The present invention is a silicon single crystal wafer grown by the Czochralski method, the silicon single crystal wafer in which an wafer entire plane is an N region located outside OSFs which are generated in the form of a ring when thermal oxidation treatment is performed and contains no defect region detected by the RIE process. As a result, a silicon single crystal wafer which belongs to none of a vacancy-rich V region, an OSF region, a Dn region in an Nv region, the Dn region in which a defect detected by the Cu deposition process is generated, and an interstitial silicon-rich I region and can improve the TDDB characteristic which is the time dependent breakdown characteristic of an oxide film more reliably than a known silicon single crystal wafer is provided, and the silicon single crystal wafer is provided under stable production conditions.

### TECHNICAL FIELD

The present invention relates to a silicon single crystal wafer which is none of the following defect regions, a V region, an OSF region, and an I region, and has good oxide dielectric breakdown voltage characteristics, a method for producing a silicon single crystal or a method for producing a silicon single crystal wafer, and a semiconductor device.

### BACKGROUND ART

In recent years, as devices have become finer with an increase in the integration of semiconductor circuits, the quality demand for a silicon single crystal produced by the Czochralski method (hereinafter abbreviated as the CZ method), the silicon single crystal which serves as a substrate thereof, has been increased. In particular, there are defects called grown-in (Grown-in) defects, such as an FPD, an LSTD, and a COP, and caused by the growth of a single crystal, the defects which deteriorate oxide dielectric breakdown voltage characteristics and device characteristics, and importance is placed on a reduction in the density and size of these defects.

Before explaining these defects, first, what is generally known about a factor determining the concentration of vacancy-type point defects called Vacancies (Vacancies, hereinafter also abbreviated as V) which are taken in the silicon single crystal and the concentration of interstitial silicon point defects called Interstitial (Interstitial-Si, hereinafter also abbreviated as I) which are taken in the silicon single crystal will be described.

In the silicon single crystal, a V region is a region containing many Vacancies, that is, concave portions or hole-like portions which are caused by the lack of silicon atoms, an I region is a region containing many dislocations and extra masses of silicon atoms which are caused by the extra existence of silicon atoms, and, between the V region and the I region, there is a neutral (Neutral, hereinafter also abbreviated as N) region which does not have (hardly has) the lack or excess of atoms. In addition, it has been found that the above-mentioned grown-in defects (such as FPDs, LSTDs, and COPs) are generated only when V and I are in an supersaturated state, and, even when the distribution of atoms is somewhat nonuniform, if V and I are not supersaturated, they are not present as the grown-in defects which are agglomerated point defects.

It has been confirmed that the concentrations of the these point defects are determined by the relationship between the pulling rate (the growth rate) of a crystal and the temperature gradient G near the solid-liquid interface in the crystal in the CZ method and defects called OSFs (Oxidation Induced Stacking Faults) are distributed in the form of a ring (hereinafter also referred to as an OSF ring) near the boundary between the V region and the N region when seen in a cross section perpendicular to the crystal growth axis. These defects caused by the growth of a crystal are described in detail in Japanese Unexamined Patent Publication (Kokai) No. 2002-201093, for example. FIG. 6 is a diagram showing the relationship between defect regions and the pulling rate of a silicon single crystal grown by the CZ method described in Japanese Unexamined Patent Publication (Kokai) No. 2002-201093.

The defects caused by a crystal are obtained as a defect distribution map shown in FIG. 6 when the growth rate is changed from high to low in the crystal axis direction in a CZ pulling apparatus using a furnace structure (a hot zone: hereinafter also referred to as a HZ) with a small temperature gradient G near the solid-liquid interface.

As a result of classification of these defects caused by the growth of a crystal, it has been found that, when, for example, the growth rate is relatively high, such as the rate equal to or higher than about 0.6 mm/min, the grown-in defects such as FPDs, LSTDs, and COPs caused by a void which is a cluster of vacancy-type point defects (Vacancies) are present in almost the entire area in the crystal diameter direction at high densities, and a region in which these defects are present is called a V region.

Then, when the growth rate is gradually decreased, the OSF ring, which has appeared on the periphery of the crystal, begins to shrink toward the inside of the crystal and eventually disappears.

When the growth rate is further decreased, an N region which hardly has the excess or lack of V and I appears. It has been found that, since, in the N region, the concentrations of V and I are equal to or lower than the saturation concentration though the distribution thereof is nonuniform, the V and I do not agglomerate into grown-in defects.

The N regions are classified into an Nv region in which the number of V is predominant and an Ni region in which the number of I is predominant.

It has been known that, when heat treatment is performed, in the Nv region, many oxide precipitates (hereinafter referred to as BMDs (Bulk Micro Defects)) are formed; in the Ni region, oxygen precipitation hardly occurs. As described above, in the Ni region, even if heat treatment is performed, oxygen precipitation hardly occurs, that is, the density of BMDs is low, resulting in a weak ability to perform gettering on contamination if contamination occurs during the device process.

As a method for solving this problem, rapid thermal annealing is performed on a wafer as disclosed in Japanese Unexamined Patent Publication (Kokai) No. 2001-503009. It has been known that, by performing the rapid thermal annealing, it becomes possible to form oxide precipitates in the wafer bulk even in the Ni region.

Moreover, as shown in FIG. 6, when the growth rate is further decreased, I is supersaturated. As a result, grown-in defects of LID (Large Dislocation: an abbreviation of an interstitial dislocation loop, such as LSEPD and LEPD), which is considered to be a dislocation loop into which I gathers, are present at low densities, and such a region is called an I-Rich region.

Based on these facts, by slicing and polishing the single crystal which was grown while controlling the growth rate such that an N region was obtained in an entire region along the radial direction from the center of the crystal, it is possible to obtain a wafer whose entire plane becomes an N region, the wafer with exceedingly few grown-in defect.

Japanese Unexamined Patent Publication (Kokai) No. 2002-201093 discloses the fact that a region (hereinafter referred to as a Dn region) in which the oxide dielectric breakdown voltage characteristics are degraded is present near the OSF region even in the Nv region, the region contains a defect which is detected by the Cu deposition process, and the defect degrades a TZDB (Time Zero Dielectric Breakdown) characteristic which is one of the oxide dielectric breakdown voltage characteristics. The TZDB characteristic is used for evaluating the field intensity at which a breakdown of an oxide film occurs at the moment when an electric field is applied to the oxide film, and is an evaluation of a so-called initial breakdown.

In addition, it discloses a fact that, when the growth rate of a silicon single crystal which is being pulled upwardly is gradually decreased, by pulling the crystal upwardly while controlling the growth rate to become a growth rate between the growth rate at a boundary where the defects which remain after the disappearance of the OSF ring and are detected by the Cu deposition process disappear and the growth rate at a boundary where an interstitial dislocation loop occurs when the growth rate is further decreased gradually, it is possible to obtain a silicon single crystal wafer containing only an N region (an (Nv−Dn)+Ni region in FIG. 6) in which the TDB characteristic is not decreased.

### DISCLOSURE OF INVENTION

However, in recent devices, as typified by flash memory, the long-term reliability, that is, the time dependent breakdown characteristic, of an oxide film is important. As a result of a close study of the TDDB (Time Dependent Dielectric Breakdown) characteristic which is the time dependent breakdown characteristic, the inventors have found that even the (Nv−Dn)+Ni region described in Japanese Unexamined Patent Publication (Kokai) No. 2002-201093 contains a region in which the TDDB characteristic is decreased.

The present invention has been made in view of the problems described above, and an object thereof is to provide a silicon single crystal wafer which belongs to none of a vacancy-rich V region, an OSF region, a Dn region in an Nv region, the Dn region in which a defect detected by the Cu deposition process is generated, and an interstitial silicon-rich I region and can improve the TDDB characteristic which is the time dependent breakdown characteristic of an oxide film more reliably than a known silicon single crystal wafer, and to provide the silicon single crystal wafer under stable production conditions.

To achieve the above object, the present invention provides a silicon single crystal wafer grown by the Czochralski method, wherein an wafer entire plane is an N region located outside OSFs which are generated in the form of a ring when thermal oxidation treatment is performed and contains no defect region detected by the RIE process.

As a result of a study conducted by the inventors on the silicon single crystal wafer by the CZ method, it has been found that, even in the (Nv−Dn)+Ni region described in Japanese Unexamined Patent Publication (Kokai) No. 2002-201093, if a defect region detected by the RIE (Reactive Ion Etching) process is present in this region, the TDDB characteristic is degraded by this defect.

However, when a silicon single crystal wafer is such a silicon single crystal wafer of the invention, the silicon single crystal wafer in which an wafer entire plane is an N region located outside OSFs and contains no defect region detected by the RIE process, a high-quality silicon single crystal wafer having an oxide film whose time dependent breakdown characteristic is highly resistant to degradation even if a device is fabricated therefrom is obtained.

At this time, it is possible that rapid thermal annealing is performed on the silicon single crystal wafer.

As described above, with the silicon single crystal wafer subjected to the rapid thermal annealing, it is possible to generate BMDs in a bulk by heat treatment in a device production process or the like in an Ni region in which oxygen precipitation does not occur easily. Therefore, the silicon single crystal wafer is a silicon single crystal wafer having an oxide film whose time dependent breakdown characteristic is resistant to degradation even if a device is fabricated therefrom and having a high gettering capability.

Moreover, the invention provides a silicon single crystal wafer grown by the Czochralski method, wherein an wafer entire plane is an N region located outside OSFs which are generated in the form of a ring when thermal oxidation treatment is performed, and a defect region detected by the RIE process and an Ni region in which oxygen precipitation does not occur easily are not present in the wafer entire plane.

With such a silicon single crystal wafer, since it is the N region located outside the OSFs and the defect region detected by the RIE process and the Ni region in which oxygen precipitation does not occur easily are not present in the wafer entire plane, the silicon single crystal wafer becomes a silicon single crystal wafer having an oxide film whose time dependent breakdown characteristic is resistant to degradation even if a device is fabricated therefrom and having a high gettering capability because BMDs are easily formed in a bulk by heat treatment.

Furthermore, the invention provides a method for producing a silicon single crystal, wherein when a silicon single crystal is grown by the Czochralski method, the crystal is grown by performing control so that the growth rate becomes a growth rate between the growth rate at a boundary where a defect region which is detected by the RIE process and remains after the disappearance of an OSF ring disappears when the growth rate of the silicon single crystal which is being pulled upwardly is decreased gradually and the growth rate at a boundary where an interstitial dislocation loop is generated when the growth rate is further decreased.

From the silicon single crystal produced by the method of the invention for producing a silicon single crystal, it is possible to obtain a silicon single crystal wafer, which is an N region located outside the OSFs and contains no defect region detected by the RIE process more reliably and stably. That is, it is possible to obtain a high-quality silicon single crystal wafer having an oxide film whose time dependent breakdown characteristic is highly resistant to degradation even if a device is fabricated therefrom.

In addition, a method for producing a silicon single crystal wafer is provided, the method by which a silicon single crystal is grown by the method of the invention for producing a silicon single crystal, a silicon single crystal wafer is sliced from the silicon single crystal, and rapid thermal annealing is performed on the silicon single crystal wafer.

With such a method for producing a silicon single crystal wafer, since the rapid thermal annealing is performed, it is possible to generate BMDs in a bulk even in an Ni region in which oxygen precipitation does not occur easily, making it possible to obtain a silicon single crystal wafer having an oxide film whose time dependent breakdown characteristic is resistant to degradation even if a device is fabricated therefrom and also having a high gettering capability.

Moreover, the invention provides a method for producing a silicon single crystal wherein, when a silicon single crystal is grown by the Czochralski method, the crystal is grown in a region which is an N region located outside an OSF ring which appears in the form of a ring when heat treatment is performed on the silicon single crystal wafer thus grown, the region containing no defect region detected by the RIE process and no Ni region in which oxygen precipitation does not occur easily.

From the silicon single crystal produced by the method of the invention for producing a silicon single crystal, it is possible to obtain a silicon single crystal wafer more reliably and stably, the silicon single crystal wafer in which a defect region resulting from the RIE process and an Ni region in which oxygen precipitation does not occur easily are not present. This makes it possible to obtain a silicon single crystal wafer having an oxide film whose time dependent breakdown characteristic is resistant to degradation even if a device is fabricated therefrom and also having a high gettering capability because BMDs are easily formed in a bulk.

Furthermore, the invention provides a semiconductor device using any one of the silicon single crystal wafer of the invention, a silicon single crystal wafer sliced from a silicon single crystal produced by the method of the invention for producing a silicon single crystal, and a silicon single crystal wafer produced by the method of the invention for producing a silicon single crystal wafer.

Such a semiconductor device is a high-quality semiconductor device having an oxide film with good time dependent breakdown characteristic.

As described above, according to the invention, it is possible to provide a silicon single crystal wafer having a high-breakdown voltage oxide film with good time dependent breakdown characteristic because it is none of the following defect regions, a V region, an OSF region, and an I region and contains no defect detected by the RIE process, and provide a semiconductor device using such a silicon single crystal wafer reliably and stably.

### BRIEF DESCRIPTION OF DRAWINGS

FIG. 1 is a schematic diagram showing an example of an apparatus for pulling a silicon single crystal upwardly;

FIG. 2 is an explanatory diagram showing how to hollow a longitudinally-cut sample to obtain a wafer shape;

FIG. 3(a) is an X-ray topography image. FIG. 3(b) is a defect map measured by the RIE process;

FIG. 4 is a graph showing an evaluation result of the TDDB characteristic in each defect region;

FIG. 5 is an explanatory diagram showing the relationship between the single crystal growth rate and the crystal defect distribution in the experiment conducted by the inventors;

FIG. 6 is an explanatory diagram showing the relationship between the single crystal growth rate and the crystal defect distribution; and

FIG. 7 is an explanatory diagram explaining an outline of the RIE process.

### BEST MODE FOR CARRYING OUT THE INVENTION

Hereinafter, an embodiment of the present invention will be described; however, the present invention is not limited thereto.

Before explanation, the RIE process and the Cu deposition process will be described in advance.

### 1) RIE Process

As a method for evaluating a micro defect containing silicon oxide (hereinafter referred to as SiOx) in a semiconductor single crystal substrate while providing resolving power in the depth direction, a method disclosed in Japanese Patent No. 3451955, for example, is known. This method performs high-selective anisotropic etching such as reactive ion etching on a principal surface of a substrate by a predetermined thickness, and performs an evaluation of a crystal defect by detecting the remaining etching residue.

Since a region in which a crystal defect containing SiOx is formed and a region in which a crystal defect containing no SiOx is not formed have different etching rates (the etching rate of the former region is lower than that of the latter region), when the etching described above is performed, a conical projection having a crystal defect containing SiOx as a vertex remains on the principal surface of the substrate.

In this method, the crystal defect becomes evident in the form of a projection portion by anisotropic etching, making it possible to detect even a minute defect easily.

Hereinafter, a specific procedure of the RIE process will be described with reference to FIG. 7, taking up a crystal defect evaluation procedure disclosed in Japanese Patent No. 3451955 as an example.

In a silicon single crystal wafer 100 shown in FIG. 7(a), oxide precipitates (BMDs 200), due to precipitation of supersaturated oxygen dissolved in the silicon single crystal wafer 100 as SiOx by heat treatment, are formed.

When an evaluation of a crystal defect is performed by the above-mentioned RIE process by using this silicon single crystal wafer 100 as a sample, etching is performed on the BMDs 200 contained in the silicon single crystal wafer 100 in an atmosphere of halogen-based mixed gas (for example, HBr/Cl₂/He+O₂) from the principal surface of the silicon single crystal wafer 100 by anisotropic etching with a high selection ratio by using a commercial RIE apparatus, for example. Then, as shown in FIG. 7(b), conical projections caused by the BMDs 200 are formed as etching residues (hillocks) 300. Based on the hillocks 300, it is possible to evaluate the crystal defect.

For example, by counting the number of hillocks 300 thus obtained, it is possible to obtain the density of BMDs 200 in the silicon single crystal wafer 100 in an etched area.

### 2) Cu Deposition Process

This process forms an insulator film (a SiO₂ film when silicon is used) having a predetermined thickness by using an oxidizing furnace on the front surface of a semiconductor wafer, and breaks down the insulator film in a defect part formed near the front surface of the wafer, and thereby depositing (deposition) an electrolytic substance such as Cu in the defect part.

In other words, when a voltage is first applied to an oxide film formed on the front surface of the wafer in a solution in which Cu ions are dissolved, a part of the oxide film, the part containing a defect or the like, passes a larger amount of current than a part containing no defect. As a result, Cu ions turn into Cu and are deposited in the defect part. The Cu deposition process is an evaluation method using this phenomenon.

It has been known that a defect such as a COP is present in a part where the oxide film tends to be degraded.

By using a collimated light or directly making a visual check of a defect portion of the wafer, the portion in which Cu has been deposited, the distribution and density can be evaluated. Furthermore, the distribution and density can be checked by using an optical microscope, a scanning electron microscope (SEM), or the like. Moreover, by performing a cross-section observation with a transmission electron microscope (TEM), a position in which Cu has been deposited in the depth direction, that is, a defect position can be identified.

As for the growth of a silicon single crystal by the CZ method, the inventors closely studied a defect detected by the RIE process and the time dependent breakdown characteristic (TDDB characteristic) of an oxide film near a boundary between a V region and an I region.

As a result of an experiment, which will be described later, having been conducted, the inventors have found that a region affecting the TDDB characteristic is present in the (Nv−Dn)+Ni region described in Japanese Unexamined Patent Publication (Kokai) No. 2002-201093. More specifically, the inventors have found that, in part of the Nv region, a region in which a defect is detected by the RIE process, though no defect is detected by the Cu deposition process, is present, and the TDDB characteristic is decreased in the defect region resulting from the RIE process.

Based on these facts, the inventors have found that, if an wafer entire plane can be turned into a region which is an N region located outside an OSF region and includes no defect region detected by the RIE process, it is possible to obtain a wafer reliably and stably, the wafer which includes none of the above-described various grown-in defects and can improve the TDDB characteristic.

Hereinafter, an experiment based on which the present invention was made will be described.

### Experiment

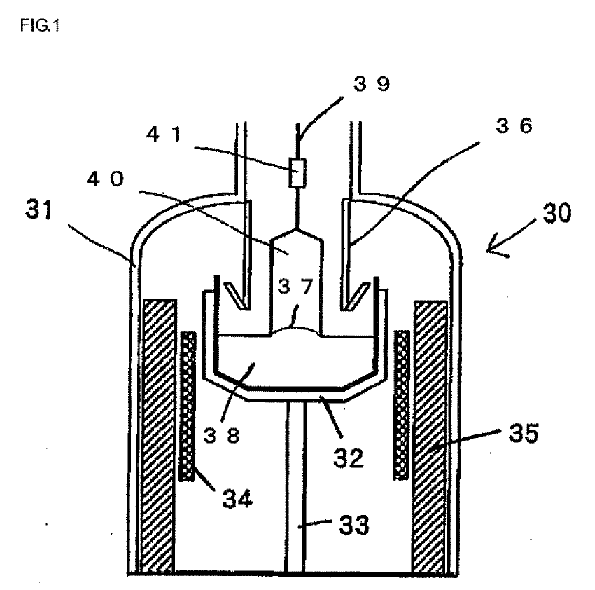

First, a single crystal having a conductive type of p-type, a diameter of 12 inches (300 mm) and orientation <100> was pulled upwardly by using an MCZ method single crystal pulling apparatus (which applies a traverse magnetic field) shown in FIG. 1 while gradually decreasing the growth rate (the pulling rate).

Here, the single crystal pulling apparatus of FIG. 1 will be described.

The single crystal pulling apparatus 30 includes a pull chamber 31, a crucible 32 provided inside the pull chamber 31, a heater 34 placed around the crucible 32, a crucible-holding shaft 33 and a rotating mechanism (not shown) thereof which rotate the crucible 32, a seed chuck 41 holding a silicon seed crystal, a wire 39 pulling the seed chuck 41 upwardly, and a winding mechanism (not shown) which rotates or winds up the wire 39. The crucible 32 is provided with a quartz crucible on the internal side thereof containing silicon melt (molten silicon) 38 and a graphite crucible on the outside thereof. Moreover, around the outside of the heater 34, an insulating material 35 is placed.

In addition, according to the production conditions, a ring-shaped graphite cylinder (gas flow-guide cylinder) 36 can be provided as shown in FIG. 1, or ring-shaped outer insulating material (not shown) can be provided around a solid-liquid interface 37 of a crystal.

Furthermore, it is also possible to blow coolant gas or provide a tubular cooling apparatus, which cools a single crystal by blocking radiant heat. Moreover, it is possible to use a so-called MCZ method by which a single crystal is grown stably by suppressing convention of the melt by horizontally placing an unillustrated magnet on the outside of the pull chamber 31 and applying a traverse or vertical magnetic field to the silicon melt 38.

These parts of the apparatus can be made similar to those used in a known apparatus, for example.

Next, a single crystal growth method by the single crystal pulling apparatus 30 described above will be described. First, silicon high-purity polycrystal material is heated in the crucible 32 to a melting point (about 1420° C.) or higher and is melted. Next, a tip of the seed crystal is brought into contact with or dipped into the silicon melt 38 at roughly the center of the surface thereof by winding off the wire 39. Then, the growth of a silicon single crystal 40 is started by rotating the crucible-holding shaft 33 in an appropriate direction and pulling the seed crystal upwardly by rotating and winding the wire 39. After that, the virtually cylindrical silicon single crystal 40 can be obtained by appropriately adjusting the pulling rate and the temperature.

In this experiment, when the silicon single crystal was pulled upwardly, control was performed so that the growth rate was gradually decreased from the head of the crystal to the tail thereof in a range from 0.7 mm/min to 0.4 mm/min. Moreover, the single crystal was produced such that the oxygen concentration of the crystal became 23 to 25 ppma (ASTM '79 value).

Then, the silicon single crystal ingot, which had been pulled upwardly, was cut longitudinally in the crystal axis direction, whereby a plurality of plate-like blocks were produced.

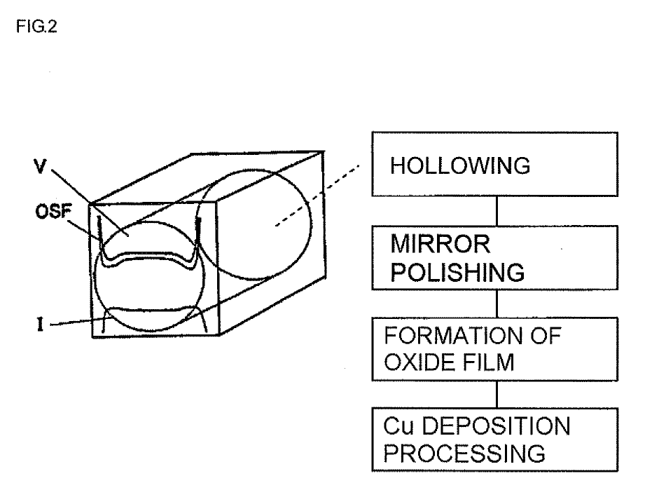

As for two of these blocks, the distribution status of defect regions such as a V region was examined by WLT (wafer lifetime) measurement (for which WT-85 manufactured by SEMILAB Co., Ltd. was used as a measuring instrument) and measurement of OSF regions, and the growth rate at each region boundary was checked. Moreover, as shown in FIG. 2, another of the longitudinally-cut samples was hollowed to obtain a wafer shape having a diameter of 8 inches. One of them was subjected to mirror finish, and, after a thermal oxide film was formed on the front surface of the wafer, the distribution status (that is, a Dn region) of oxide film defects was checked by the Cu deposition process.

Incidentally, as for the measurement of WLT, one of the longitudinally-cut samples was sliced in the crystal axis direction so that each piece has a length of 10 cm, and these pieces were subjected to heat treatment in a wafer heat treatment furnace at 650° C. for 2 hours in an atmosphere of nitrogen, and, after the temperature was increased to 800° C. and kept at that temperature for 4 hours, the atmosphere was changed to an oxygen atmosphere. Then, after the temperature was increased to 1000° C. and kept at that temperature for 16 hours, the pieces were cooled and taken out of the furnace. After that, the X-ray topography images thereof were taken, and a wafer lifetime map was created by SEMILAB WT-85.

Moreover, as for the measurement of the OSF regions, one of the longitudinally-cut samples was subjected to OSF heat treatment and then secco etching was performed thereon, and the distribution status of OSFs was checked.

Furthermore, as measurement of defect regions by the Cu deposition process, the Cu concentration in a methanol solvent was adjusted to 0.4 to 30 ppm, Cu deposition was performed at an applied voltage of 5 MV/cm for 5 minutes, and cleaning and drying were performed. Then, visual observation of the distribution of deposited copper was made.

Based on the results of treatment performed on these samples, the V region, the OSF region, the Nv region, the Ni region, the I region, and the Dn region were identified.

The growth rates at the boundaries of the single crystal, which had been pulled upwardly, were as follows.

| | |
|---|---|
| V region/OSF region boundary: | 0.596 mm/min |
| OSF disappearance boundary: | 0.587 mm/min |
| Cu deposition defect disappearance boundary: | 0.566 mm/min |
| Nv region/Ni region boundary: | 0.526 mm/min |
| Ni region/I region boundary: | 0.510 mm/min |

Next, a relative positional relationship between the V region and the like, the defect region resulting from the Cu deposition process, and the defect region resulting from the RIE process was obtained by using the similar longitudinally-cut sample.

First, the sample was hollowed (refer to FIG. 2) to obtain a wafer shape having a diameter of 8 inches with the identified Nv region placed at the center. Then, the sample underwent a series of processes for producing a polished wafer, such as slicing, lapping, etching, and polishing, to produce a polished wafer (hereinafter referred to as a PW), and this wafer was used as an evaluation sample wafer.

A first evaluation sample wafer was subjected to heat treatment in a wafer heat treatment furnace at 650° C. for 2 hours in an atmosphere of nitrogen, and, after the temperature was increased to 800° C. and kept at that temperature for 4 hours, the atmosphere was changed to an oxygen atmosphere. Then, after the temperature was increased to 1000° C. and kept at that temperature for 16 hours, the sample was cooled and taken out of the furnace. After that, an X-ray topography image thereof was taken.

On a second evaluation sample wafer, etching was performed by using a magnetron RIE apparatus (Precision 5000 Etch manufactured by Applied Materials, Inc.). The reaction gas was HBr/Cl₂/He+O₂ mixed gas. Then, residuary projections after etching were measured by a laser scattering foreign body inspection apparatus (SP1 manufactured by KLA-Tencor Corporation).

As for a third evaluation sample wafer, a defect generation region was visually observed by performing the Cu deposition process. The measurement conditions were the same as those described above.

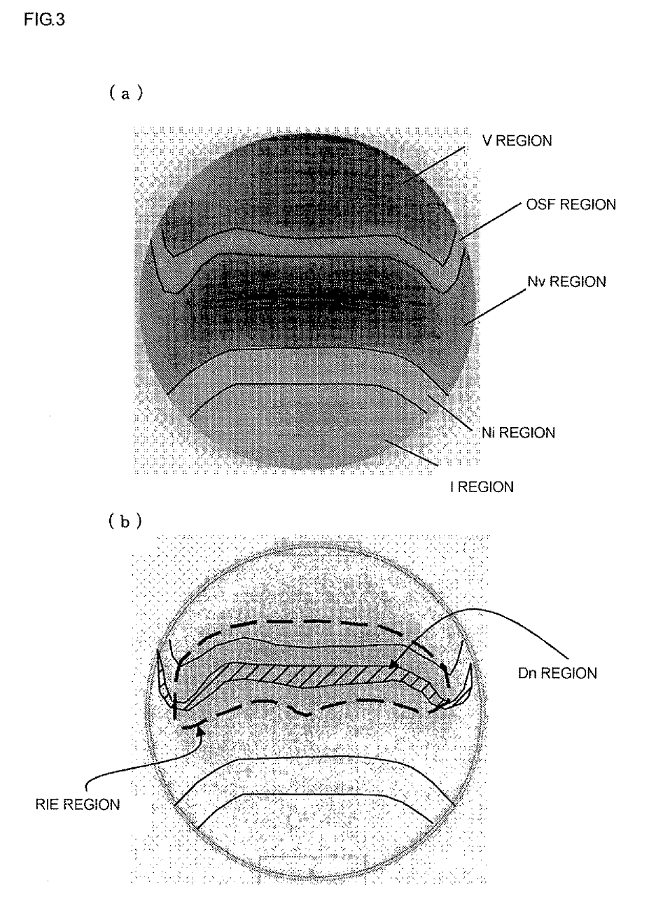

The evaluation results are shown in FIG. 3. FIG. 3(a) is an X-ray topography image. Moreover, FIG. 3(b) is a defect map measured by the RIE process. An area surrounded by a dotted line is a region in which oxide precipitates (defects) were detected by the RIE process. Incidentally, in FIG. 3(b), the V region, the OSF region, the Nv region, the Ni region, the I region which were measured in FIG. 3(a) and the region (the shaded area) in which defects were observed by the Cu deposition process are collectively shown.

As is clear from FIGS. 3(a) and 3(b), the defect region detected by the RIE process is present in the V region and the Nv region, which border on the OSF region. Moreover, it has been found that the defect region (the shaded area of FIG. 3(b)) detected by the Cu deposition process is present in the Nv region bordering on the OSF region and the range of the defect region is narrower than the range of the defect region detected by the RIE process. That is, in the Nv region, the defect region detected by the RIE process contains the defect region detected by the Cu deposition process.

Incidentally, the growth rate at which the defect region resulting from the RIE process disappeared was as follows.

| | |
|---|---|
| Disappearance boundary of defects | 0.536 mm/min |
| resulting from the RIE process: | |

This is between the growth rate at the above-described Cu deposition defect disappearance boundary and the growth rate at the above-described Nv region/Ni region boundary.

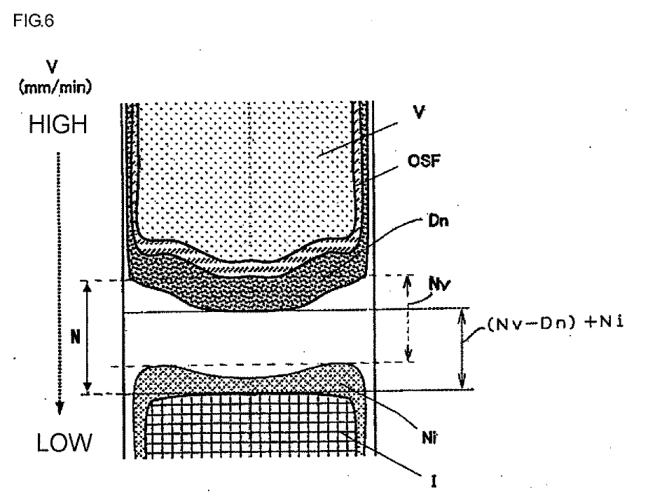

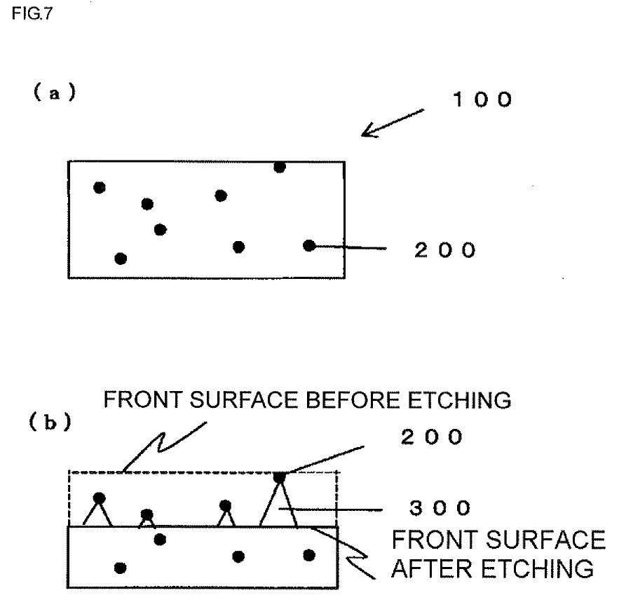

The relationship between the growth rate of the silicon single crystal and each defect distribution, the relationship obtained by this experiment, is shown in FIG. 5. Incidentally, the defect region in the Nv region is assumed to be divided and defined as follows:

an Nv (Dn) region, which is an Nv region and a region in which a defect is detected by the Cu deposition process,

an Nv (RIE-Dn) region which is an Nv region and a region in which a defect is detected by the RIE, process and is not detected by the Cu deposition process, and

a Super Nv region (Nv-RIE region), which is an Nv region and a region in which no defect is detected by the RIE process.

Here, based on the above-described relationship between the growth rate and the defect distribution, the growth rate was controlled such that each of the Nv (Dn) region, the Nv (RIE-Dn) region, and the Super Nv region could be targeted, the crystal which had been pulled upwardly was processed to obtain a mirror-finished wafer, and the TDDB characteristic which was the oxide dielectric breakdown voltage characteristic was evaluated.

Incidentally, the MOS structure used for the evaluation had a gate oxide film thickness of 25 nm and an electrode area of 4 mm², and the criteria for an initial failure (α mode), a random failure (β mode), and an intrinsic failure (γ mode) indicating the limit of the material are that Qbd (Charge to Breakdown: the charge amount that causes a breakdown) is less than 0.01 C/cm², Qbd is 0.01 C/cm² or more but less than 5 C/cm², and Qbd is equal to or more than 5 C/cm², respectively.

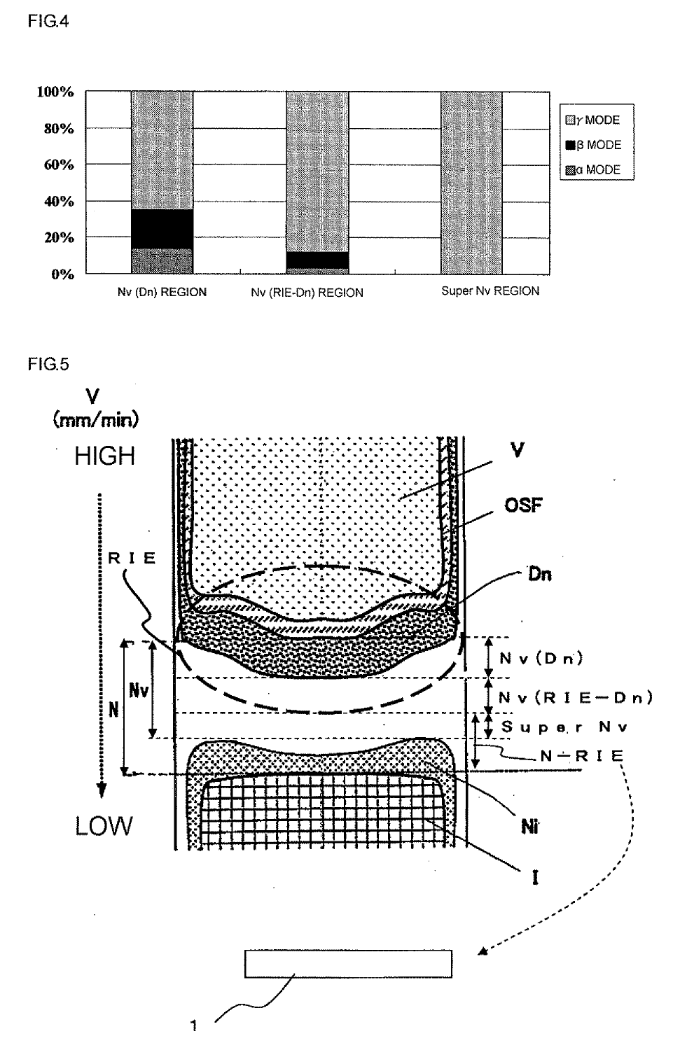

The TDDB measurement results of the three regions defined as described above are shown in FIG. 4.

As is clear from FIG. 4, the rate of occurrence of γ mode indicating the intrinsic breakdown of the oxide film was excellent and 100% in the Super-Nv region; on the other hand, the rate of occurrence of γ mode was 88% in the Nv (RIE-Dn) region and 65% in the Nv (Dn) region.

That is, even in a region which is an Nv region and in which no defect is detected by the Cu deposition process, the region which was previously assumed to be good due to the TZDB characteristic thereof, if the region is a region (Nv (RIE-Dn) region) in which a defect is detected by the RIE process, the oxide film has poor long-term reliability. In other words, in the silicon single crystal wafer disclosed in Japanese Unexamined Patent Publication (Kokai) No. 2002-201093, the TDDB characteristic is not necessarily good.

However, as in the Super Nv region of the present invention, in a region in which a defect resulting from the RIE process is not generated, a high-quality silicon single crystal wafer with not only good TZDB characteristic but also good TDDB characteristic is obtained.

Incidentally, the C-mode good chip yields of TZDB are 100% (the Super Nv region), 99% (the Nv (RIE-Dn) region), and 92% (the Nv (Dn) region).

Moreover, when an evaluation of the TDDB characteristic and the TZDB characteristic was performed for the Ni region in the same manner, the good results indicating that both the rate of occurrence of γ mode and the C-mode good chip yield were 100% as in the Super Nv were obtained.

As a result of the above experiment, the inventors have found that it is possible to obtain a silicon single crystal wafer not only with good TZDB characteristic but also with good TDDB characteristic by removing the defect region caused by the RIE process from the N region, and have completed the present invention.

That is, the silicon single crystal wafer of the present invention is a silicon single crystal wafer whose wafer entire plane is the N region located outside the OSF region and contains no defect region detected by the RIE process, the silicon single crystal wafer which is produced by the CZ method.

The silicon single crystal wafer 1 of the present invention is cut from an N-RIE region of the silicon single crystal as shown in FIG. 5, for example. The N-RIE region is a region, which is the N region, the region in which no defect is detected by the RIE process. As mentioned above, the RIE region is wider than the defect region Dn resulting from the Cu deposition process, and the N-RIE region contains no Dn region.

Therefore, the silicon single crystal wafer of the present invention is a high-quality silicon single crystal wafer with good TDDB characteristic in addition to good TZDB characteristic.

Moreover, when, in particular, a silicon single crystal wafer is a silicon single crystal wafer whose wafer entire plane is the N region, the silicon single crystal wafer in which the defect region resulting from the RIE process and the Ni region are not present, that is, the silicon single crystal wafer formed of the Super Nv region, this silicon single crystal wafer also has good TDDB characteristic. In addition, the silicon single crystal wafer is a silicon single crystal wafer containing no Ni region in which oxygen precipitation does not occur easily, the silicon single crystal wafer which is entirely the Nv region (except for the RIE region). Therefore, by performing heat treatment, BMDs are formed in the bulk, whereby the silicon single crystal wafer becomes a silicon single crystal wafer with good gettering capability.

On the other hand, even when a silicon single crystal wafer is an N region containing an Ni region, if the silicon single crystal wafer has been subjected to rapid thermal annealing, it is possible to generate the BMDs at the time of oxygen precipitation heat treatment even in the Ni region in which oxygen precipitation does not occur easily. This makes it possible to obtain an adequately high gettering capability.

It is possible to change the concentration distribution in the depth direction of the BMDs with the processing conditions in the rapid thermal annealing. By performing the rapid thermal annealing, redistribution by injection or diffusion of the vacancy-type point defects V and disappearance caused by recombination of the vacancy-type point defect V and the interstitial silicon I which is an interstitial silicon-type point defect take place, whereby it is possible to control the concentration profile of V. Thereafter, when oxygen precipitation heat treatment is performed, it is possible to form the BMDs in the bulk according to the concentration profile of V.

In addition, a semiconductor device using the above-described silicon single crystal wafer of the present invention is a high-quality semiconductor device with good TDDB characteristic, and can meet the requirements of the marketplace.

Moreover, the above-described silicon single crystal wafer of the present invention can be obtained by slicing the wafer from a silicon single crystal obtained by a method of the present invention for producing a silicon single crystal, the method that will be described below. At this time, it is possible to use the pulling apparatus shown in FIG. 1, for example. The structure of this pulling apparatus has been described above.

In the method of the present invention for producing a silicon single crystal, a crystal is grown by performing control such that the growth rate becomes a growth rate between the growth rate at a boundary where a defect region which is detected by the RIE process and remains after the disappearance of the OSF ring disappears when the growth rate of the silicon single crystal which is being pulled upwardly is decreased gradually and the growth rate at the boundary where an interstitial dislocation loop is generated when the growth rate is further decreased.

That is, control is performed so that the growth rate (the pulling rate) of the silicon single crystal falls within a range of the N-RIE region, and the silicon single crystal is pulled upwardly in that region.

Moreover, a crystal is grown in a region which is an N region located outside an OSF ring which appears in the form of a ring when heat treatment is performed on the silicon single crystal wafer thus grown, the region containing no defect region detected by the RIE process and no Ni region in which oxygen precipitation does not occur easily.

That is, control is performed so that the growth rate of the silicon single crystal falls within a range of the Super Nv region (Nv-RIE region), and the silicon single crystal is pulled upwardly in that region.

In order to pull the silicon single crystal with an intended defect region upwardly by performing control so that the growth rate falls within a certain range as described above, it is preferable simply to conduct a preliminary test in advance on the relationship between the growth rate of the silicon single crystal and the defect region of the silicon single crystal pulled upwardly at that growth rate.

For example, the above-described experiment conducted by the inventors may be performed as the preliminary test. In other words, the silicon single crystal is pulled upwardly while decreasing the growth rate gradually, and the defect regions are examined in the manner as described above. Then, based on the obtained relationship between the growth rate and the defect region, a single crystal is pulled upwardly in an intended defect region.

Here, if the silicon single crystal is pulled upwardly while performing control so that the growth rate thereof falls within a range of the N-RIE region based on the above-described example, the silicon single crystal is pulled upwardly at 0.536 mm/min (the disappearance boundary of defects resulting from the RIE process) to 0.510 mm/min (the Ni region/I region boundary).

Moreover, when the silicon single crystal is pulled upwardly while performing control so that the growth rate thereof falls within a range of the Super Nv region (Nv-RIE region), the silicon single crystal is pulled upwardly at 0.536 mm/min (the disappearance boundary of defects resulting from the RIE process) to 0.526 mm/min (the Nv region/Ni region boundary).

In this way, by performing control so that the growth rate becomes the growth rate of an intended defect region, the defect region containing no defect region resulting from the RIE process, pulling the silicon single crystal upwardly, and slicing the silicon single crystal, it is possible to obtain a silicon single crystal wafer of the present invention.

Moreover, when the silicon single crystal wafer containing the N-RIE region, in particular, the Ni region is obtained in the manner as described above, it is advisable to perform rapid thermal annealing. As described above, by performing the rapid thermal annealing, it is possible to form BMDs in the bulk even in the Ni region in which the BMDs do not occur easily. This makes it possible to provide an adequate gettering capability.

Incidentally, the conditions of the rapid thermal annealing performed at this time are not particularly limited, and the conditions can be set appropriately in such a way that an intended BMD profile is obtained when the heat treatment is performed in a subsequent device process or the like. An apparatus used in performing the rapid thermal annealing is also not particularly limited; for example, an apparatus similar to the known apparatus can be used.

It is to be understood that the present invention is not limited in any way by the embodiment thereof described above. The above embodiment is merely an example, and anything that has substantially the same structure as the technical idea recited in the claims of the present invention and that offers similar workings and benefits falls within the technical scope of the present invention.

1-7. (canceled)

8. A silicon single crystal wafer grown by the Czochralski method, wherein
an wafer entire plane is an N region located outside OSFs, which are generated in the form of a ring when thermal oxidation treatment is performed and contains no defect region detected by the RIE process.

9. The silicon single crystal wafer according to claim 8, wherein rapid thermal annealing is performed on the silicon single crystal wafer.

10. A silicon single crystal wafer grown by the Czochralski method, wherein
an wafer entire plane is an N region located outside OSFs, which are generated in the form of a ring when thermal oxidation treatment is performed, and a defect region detected by the RIE process and an Ni region in which oxygen precipitation does not occur easily are not present in the wafer entire plane.

11. A method for producing a silicon single crystal, wherein
when a silicon single crystal is grown by the Czochralski method, the crystal is grown by performing control so that the growth rate becomes a growth rate between the growth rate at a boundary where a defect region which is detected by the RIE process and remains after the disappearance of an OSF ring disappears when the growth rate of the silicon single crystal which is being pulled upwardly is decreased gradually and the growth rate at a boundary where an interstitial dislocation loop is generated when the growth rate is further decreased.

12. A method for producing a silicon single crystal wafer, wherein
a silicon single crystal is grown by the method for producing a silicon single crystal according to claim 11, a silicon single crystal wafer is sliced from the silicon single crystal, and rapid thermal annealing is performed on the silicon single crystal wafer.

13. A method for producing a silicon single crystal, wherein
when a silicon single crystal is grown by the Czochralski method, the crystal is grown in a region which is an N region located outside an OSF ring which appears in the form of a ring when heat treatment is performed on the silicon single crystal wafer thus grown, the region containing no defect region detected by the RIE process and no Ni region in which oxygen precipitation does not occur easily.

14. A semiconductor device using the silicon single crystal wafer according to claim 8.

15. A semiconductor device using the silicon single crystal wafer according to claim 9.

16. A semiconductor device using the silicon single crystal wafer according to claim 10.

17. A semiconductor device using a silicon single crystal wafer sliced from a silicon single crystal produced by the method for producing a silicon single crystal according to claim 11.

18. A semiconductor device using a silicon single crystal wafer sliced from a silicon single crystal produced by the method for producing a silicon single crystal according to claim 13.

19. A semiconductor device using a silicon single crystal wafer produced by the method for producing a silicon single crystal wafer according to claim 12.
